(19) United States
(12) Patent Application Publication
(10) Pub. No.: US 2025/0246529 A1
(43) Pub. Date: Jul. 31, 2025

(54) DISPLAY DEVICE

(71) Applicant: LG Display Co., Ltd., Seoul (KR)

(72) Inventor: Hyunjun LEE, Paju-si (KR)

(21) Appl. No.: 18/787,581

(22) Filed: Jul. 29, 2024

(30) Foreign Application Priority Data
Jan. 29, 2024 (KR) 10-2024-0013308

(51) Int. Cl. H01L 23/498; H01L 23/00; H10K 59/131; H10K 59/90

(52) U.S. Cl. CPC H01L 23/49833; H01L 23/564; H10K 59/131; H10K 59/90

(57) ABSTRACT

A display apparatus includes a display panel including a display area having a plurality of pixels, a first pad area disposed around the display area, a data driving part located on the first pad area, and a connection member located on the data driving part. The connection member has different thicknesses according to a portion thereof disposed at the data driving part.

### CROSS-REFERENCE TO RELATED APPLICATION

The present application claims the benefit of and priority to Korean Patent Application No. 10-2024-0013308 filed on Jan. 29, 2024, the entire contents of which are incorporated herein by reference for all purposes.

### BACKGROUND

### Technical Field

The present disclosure relates to a display apparatus.

### Description of the Related Art

With the development of the information society, various demands for a display apparatus for displaying images are increasing. Various types of display apparatuses such as a liquid crystal display apparatus, an organic light emitting diode display apparatus, etc., are being used.

The organic light emitting display apparatus emits light by itself. Compared to the liquid crystal display apparatus, the organic light emitting display apparatus has a larger viewing angle, a more excellent contrast ratio, etc., and requires no separate backlight, so that it can be lighter and thinner and is advantageous in terms of power consumption. Also, the organic light emitting display apparatus can be driven at direct current low voltage, and has a rapid response speed and a lower manufacturing cost. Despite these advantages, organic light emitting displays also have deficiencies and drawbacks. For example, static electricity can impact the circuits that display the image, thereby reducing image quality. In addition, the layers of the display laminate can separate, which can also lead to a reduction in image quality as well as potential damage to the internal components of the display. Accordingly, it would be advantageous to have a display apparatus that overcomes these and other deficiencies with current solutions.

### BRIEF SUMMARY

The organic light emitting display apparatus may include a display panel and a data driving part, and the data driving part may be mounted on the display panel in the form of a driving chip or may be mounted on a printed circuit board attached to the display panel.

One or more aspects of the present disclosure is to provide a display apparatus capable of shielding a data driving part from static electricity.

One or more aspects of the present disclosure is to provide a display apparatus capable of forming a ground path from a display panel to a printed circuit board.

One or more aspects of the present disclosure is to provide a display apparatus capable of compensating for a step difference between the data driving part and a reinforcement part disposed adjacent to the data driving part.

According to one or more embodiments of the present disclosure, a display apparatus may include a display panel including a display area having a plurality of pixels, and a first pad area disposed around the display area, a data driving part on the first pad area, and a connection member on the data driving part. The connection member may have different thicknesses according to a portion thereof disposed at the data driving part.

According to one or more embodiments of the present disclosure, a display apparatus may include a display panel including a display area having a plurality of pixels, and a first pad area disposed around the display area, a data driving part on the first pad area, and a connection member on the data driving part. The connection member may include no inclined surface.

According to embodiments of the present disclosure, the display apparatus includes the connection member covering the data driving part, thereby shielding the data driving part from static electricity.

According to embodiments of the present disclosure, through the connection member, the ground path may be formed from the display panel to the printed circuit board.

According to embodiments of the present disclosure, the reinforcement part is disposed around the data driving part, and the reinforcement part and the conductive portion of the connection member are electrically connected, so that a ground contact area between the display panel and the printed circuit board may be further obtained.

According to embodiments of the present disclosure, the connection member is formed not to have an inclined surface, so that an adhesive force between the connection member and the underlying reinforcement part or the data driving part may be further improved.

According to embodiments of the present disclosure, the adhesive force between the connection member and the underlying reinforcement part or the data driving part is improved, so that the durability and lifespan of the display apparatus may be improved.

According to embodiments of the present disclosure, the connection member is composed of an integral connection member that prevents static electricity and performs a grounding function, resulting in an effect of uni-materialization.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

It is to be understood that both the foregoing general background and the following detailed description of the present disclosure are exemplary and explanatory in nature and are intended to provide further explanation of the disclosure rather than to limit the disclosure.

### BRIEF DESCRIPTION OF THE SEVERAL VIEWS OF THE DRAWINGS

The accompanying drawings, which are included to provide a further understanding of the disclosure, and incorporated in and constitute a part of this application, illustrate embodiments of the disclosure and together with the description serve to explain the principles and techniques of the disclosure.

FIG. 1 is a plan view of a display apparatus according to an embodiment of the present disclosure.

FIG. 2 is a cross-sectional view of the display apparatus of FIG. 1 taken along line A-A′ of FIG. 1 with the display in a flat or resting state.

FIG. 3 is a cross-sectional view of the display apparatus of FIG. 1 taken along line A-A′ of FIG. 1 with the display in a bent state.

FIG. 4 is a cross-sectional view of a display panel of the display apparatus of FIG. 2 along line B-B′ in FIG. 2

FIG. 5 is an enlarged plan view of a region Q1 of the display apparatus of FIG. 1.

FIG. 6 is a cross-sectional view of the display apparatus of taken along line C-C′ of FIG. 5.

FIG. 7 is an enlarged plan view of a region Q2 of the display apparatus of FIG. 6.

FIG. 8 is an enlarged plan view of a region Q3 of the display apparatus of FIG. 6.

FIG. 9 is an enlarged plan view of a region Q4 of the display apparatus of FIG. 6.

FIG. 10 is a cross-sectional view of a display apparatus taken along line C-C′ in FIG. 5 according to an embodiment of the present disclosure.

FIG. 11 is a cross-sectional view of a display apparatus taken along line D-D′ in FIG. 5 according to an embodiment of the present disclosure.

FIG. 12 is a cross-sectional view of a display apparatus taken along line D-D′ in FIG. 5 according to an embodiment of the present disclosure.

### DETAILED DESCRIPTION

Reference is now made in detail to aspects of the present disclosure, examples of which may be illustrated in the accompanying drawings. In the following description, when a detailed description of well-known methods, functions or configurations may unnecessarily obscure aspects of the present disclosure, the detailed description thereof may be omitted for brevity. The progression of processing steps and/or operations described is an example; however, the sequence of steps and/or operations is not limited to that set forth herein and may be changed, with the exception of steps and/or operations necessarily occurring in a particular order.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the aspects described with reference to the accompanying drawings. The present disclosure may, however, be embodied in different forms and should not be construed as limited to the aspects set forth herein. Rather, these aspects are examples and are provided so that this disclosure may be thorough and complete to assist those skilled in the art to understand the inventive concepts without limiting the protected scope of the present disclosure.

The shapes, sizes, areas, widths, heights, thicknesses, ratios, angles, numbers, the number of elements, and the like disclosed in the drawings for describing aspects of the present disclosure are merely examples, and thus, the present disclosure is not limited to the illustrated details. When the term “comprise,” “have,” “include,” “contain,” “constitute,” “made of,” “formed of,” “composed of,” or the like is used, one or more elements (e.g., layers, films, regions, components, sections, members, parts, regions, areas, portions, steps, operations, and/or the like) may be added unless a term such as “only” or the like is used. The terms used in the present disclosure are merely used to describe particular aspects, and are not intended to limit the scope of the present disclosure. The terms used herein are merely used to describe example aspects, and are not intended to limit the scope of the present disclosure. The terms of a singular form may include plural forms unless the context clearly indicates otherwise. The word “exemplary” is used to mean serving as an example or illustration. An aspect may be one or more example aspects. Aspects are example aspects. Any implementation described herein as an “example” or “aspect” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompass all the meanings of the term “may.”

In describing a positional relationship, where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” “adjacent to,” “beside,” or “next to” another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It is understood that, although the term “first,” “second,” or the like may be used herein to describe various elements (e.g., layers, films, regions, components, sections, members, parts, regions, areas, portions, steps, operations, and/or the like), these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing elements of the present disclosure, the terms “first,” “second,” “A,” “B,” “(a),” “(b),” or the like may be used. These terms are intended to identify the corresponding element(s) from the other element(s), and these terms are not used to define the essence, basis, order, or number of the elements.

For the expression that an element (e.g., layer, film, region, component, section, or the like) is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with the another element, but also indirectly contact, overlap, or the like with another element with one or more intervening elements disposed or interposed between the elements or layers, unless otherwise specified.

The terms such as a “line” or “direction” should not be interpreted only based on a geometrical relationship in which the respective lines or directions are parallel or perpendicular to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item,” may represent (i) a combination of items provided one or more of the first item, the second item, and the third item and (ii) only one of the first item, the second item, and the third item.

The expression of a first element, a second elements “and/or” a third element should be understood to encompass one of the first, second, and third elements, one of the first, second, and third elements, as well as any or all combinations of the first, second and third elements. By way of example, A, B and/or C encompass only A; only B; only C; any of A, B, and C (e.g., A, B, or C; some combination of A, B, and C (e.g., A and B; A and C; or B and C); and all of A, B, and C. Furthermore, an expression “A/B” may be understood as A and/or B. For example, an expression “A/B” can refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” For example, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various aspects of the present disclosure may be partially or entirely coupled to or combined with each other, may be technically associated with each other, or may be operated, linked or driven together in various ways. Aspects of the present disclosure may be implemented or carried out independently from each other, or may be implemented or carried out together in a co-dependent or related relationship. In one or more aspects, the components of each apparatus according to various aspects of the present disclosure are operatively coupled and configured.

Unless otherwise defined, the terms (including technical and scientific terms) used herein have the same meaning as commonly understood by one of ordinary skill in the art to which example aspects belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field. However, there may be other terms than the terms depending on the development and/or change of technology, convention, preference of technicians, etc. Therefore, the terms used herein should not be understood as limiting technical ideas, but should be understood as examples of the terms for illustrating embodiments.

Further, in a specific case, a term may be arbitrarily selected by the applicant, and in this case, the detailed meaning thereof is described herein. Therefore, the terms used herein should be understood based on not only simply the name of the terms, but also the meaning of the terms and the contents thereof.

“X-axis direction,” “Y-axis direction,” and “Z-axis direction,” should not be construed by a geometric relation only of a mutual vertical or perpendicular relation and may have broader directionality within the range that elements of the present disclosure may act functionally.

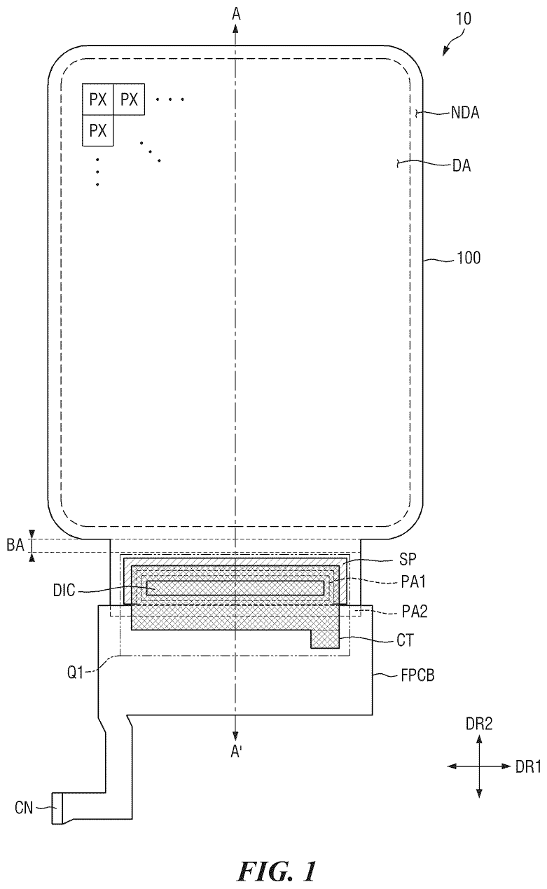

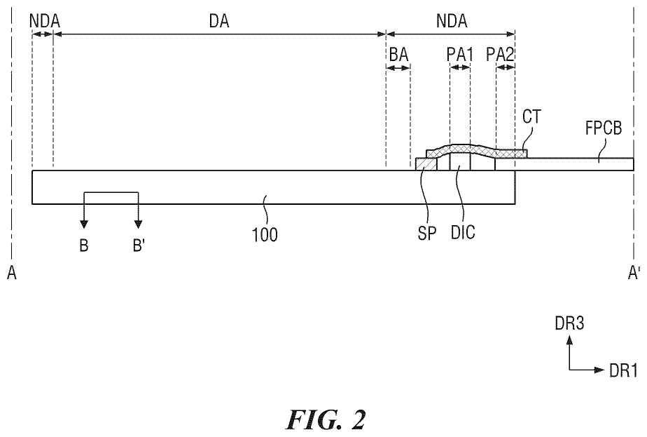

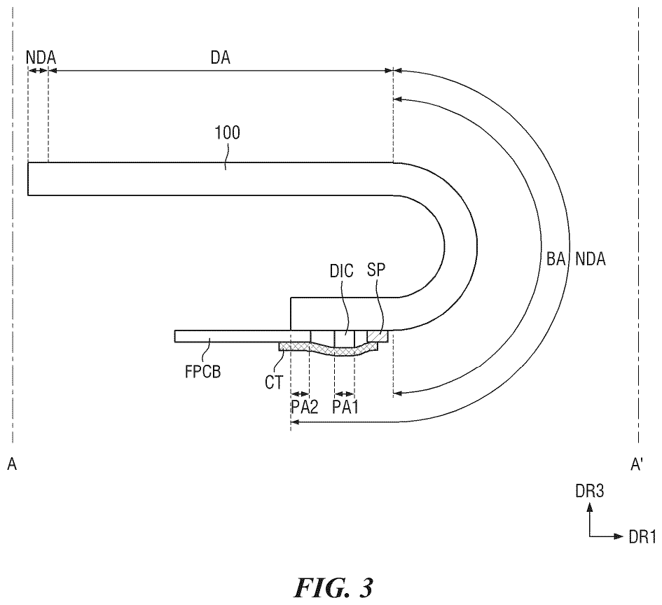

FIG. 1 is a plan view of a display apparatus 10 according to an embodiment of the present disclosure. FIG. 2 is a cross-sectional view of the display apparatus 10 taken along line A-A′ of FIG. 1 with the display in a flat or resting state. FIG. 3 is a cross-sectional view along line A-A′ in FIG. 1 with the display apparatus 10 in a bent state.

Referring to FIGS. 1 to 3, a display apparatus 10 according to an embodiment of the present disclosure may include a display panel 100. The display panel 100 may include a display area DA and a non-display area NDA disposed around the display area DA. For example, in the display panel 100, the display area DA and the non-display area NDA disposed around the display area DA may be defined. Hereinafter, all of the mentioned areas may be represented as being included in the display panel 100, or may be represented as being defined in the display panel 100.

The display area DA may include a plurality of pixels PX. The plurality of pixels PX may be arranged in a matrix form, but the pixels are not limited thereto. The display area DA may have a rectangular shape including short sides extending in a first direction DR1 and long sides extending in a second direction DR2, and is not limited thereto.

The non-display area NDA may surround the display area DA in a planar view. For example, the non-display area NDA may be arranged to surround all the long sides (or the sides extending in the second direction DR2) and all the short sides (or the sides extending in the first direction DR1) of the display area DA. However, the non-display area NDA is not limited thereto.

The non-display area NDA disposed on the bottom side of the display area DA in the second direction DR2 may protrude in the second direction DR2. A width of the protruding portion of the non-display area NDA in the first direction DR1 may be less than the width of the display panel 100 on or in which the display area DA is disposed. The non-display area NDA protruding in the second direction DR2 may include a plurality of pad areas PA1 and PA2 and a bending area BA.

The bending area BA may be disposed between the display area DA and the first pad area PA1. FIGS. 1 and 2 show that the bending area BA is located on one side end or a bottom side or bottom end of the non-display area NDA in the second direction DR2. However, embodiments of the present disclosure are not limited to this arrangement and the bending area BA may be disposed in other locations of the display apparatus 10. As shown in FIG. 3, the display panel 100 may be bent in the bending area BA. When the display panel 100 is bent in the bending area BA, the first pad area PA1 and the second pad area PA2 of the display panel 100 may be disposed to overlap the display area DA in the thickness direction, respectively.

The first pad area PA1 may be disposed between the bending area BA and the second pad area PA2. A data driving part DIC (which may also be referred to as a data driving circuit DIC) may be disposed at the first pad area PAL. The first pad area PA1 may include a plurality of first pads. The data driving part DIC may include a plurality of bumps. The first pads of the first pad area PA1 and the plurality of bumps of the data driving part DIC may be electrically connected to each other. The first pad and the bump may be electrically connected through an anisotropic conductive film (ACF), but is not limited to thereto. The first pad and the bump may also be electrically connected through ultrasonic bonding. But, embodiments of the present disclosure are not limited thereto.

The second pad area PA2 may be disposed further from the bottom of the display panel 100 in the second direction DR2 than the first pad area PAL. In an embodiment, the second pad area PA2 is disposed at a bottom of the protrusion of the non-display NDA in the second direction DR2. A printed circuit board FPCB may be attached to the second pad area PA2. The second pad area PA2 may include a plurality of second pads, and the printed circuit board FPCB may include a plurality of leads. The plurality of second pads and the plurality of leads may be electrically connected to each other. The second pad and the lead may be electrically connected through an anisotropic conductive film (ACF), but are not limited to thereto. The second pad and the lead may also be electrically connected through ultrasonic bonding. But, embodiments of the present disclosure are not limited thereto.

The display apparatus 10 according to an embodiment of the present disclosure may further include a reinforcement part SP (which may also be referred to herein as a reinforcement member, reinforcement element, support member or element, and the like) disposed around the data driving part DIC. The reinforcement part SP may surround the data driving part DIC in a plane view. For example, the reinforcement part SP may include a portion which is disposed on a first or left side of the data driving part DIC in the first direction DR1 and extends up and down in the second direction DR2, a portion which is disposed on a second or right side of the data driving part DIC in the first direction DR1 and extends up and down in the second direction DR2, and a portion which is disposed on a third or top side of the data driving part DIC in the second direction DR2 and extends to the left and right in the first direction DR1. The reinforcement part SP may have a rectangular shape having one open side which is longer than the other sides thereof (such as a “C” or “U” shape), but embodiments of the present disclosure are not limited thereto. The reinforcement part SP may not be disposed on the fourth or bottom side of the data driving part DIC in the second direction DR2. The reinforcement part SP may not be disposed between the data driving part DIC and the printed circuit board FPCB, or between the data driving part DIC and the second pad area PA2.

The display panel 100 includes the bending area BA. Therefore, when the display panel 100 is bent with respect to the bending area BA, the display panel 100 may be formed with a very thin thickness to minimize bending stress of the display panel 100. Since the data driving part DIC with relatively high rigidity (i.e., with respect to other aspects, such as the bending area BA) is disposed at the first pad area PA1, a periphery area of the data driving part DIC may be vulnerable to damage when the display panel 100 is bent.

In the case of the display apparatus 10 according to an embodiment of the present disclosure, the reinforcement part SP with high rigidity is disposed around the data driving part DIC, an thus, when the display panel 100 is bent, the rigidity of the periphery area of the data driving part DIC may be increased. In other words, the reinforcement part SP assists with reducing or preventing damage to the peripheral areas of the data driving part DIC that might otherwise be damaged during bending of the bending area BA.

The reinforcement part SP is not disposed between the data driving part DIC and the printed circuit board FPCB or between the data driving part DIC and the second pad area PA2, and thus, physical interference with the printed circuit board FPCB attached to the second pad area PA2 may be minimized or eliminated.

The printed circuit board FPCB may further include a connector CN, and may be electrically connected to a main circuit board or the like through the connector CN. However, embodiments of the present disclosure are not limited thereto.

The display apparatus 10 according to an embodiment of the present disclosure may further include a connection member CT which overlaps with the data driving part DIC, the reinforcement part SP, and the printed circuit board FPCB. The connection member CT may cover or shield the data driving part DIC. For example, the connection member CT may completely (or entirely) cover or shield the data driving part DIC. The connection member CT may shield the data driving part DIC from external static electricity by completely covering the data driving part DIC.

As shown in FIG. 2, the connection member CT may cover the data driving part DIC and overlap with the reinforcement part SP around the data driving part DIC. For example, the connection member CT may completely cover the data driving part DIC and overlap with the reinforcement part SP around the data driving part DIC. The connection member CT may overlap with a portion of the reinforcement part SP and may not overlap with another portion of the reinforcement part SP. In an embodiment, the connection member CT is implemented as a plate of a selected material, such as various metals, to cover and act as a shield for the data driving part DIC. Thus, the connection member CT may also be a connection plate, connection member, connection element, shield, shield plate, or the like. However, embodiments of the present disclosure are not limited thereto.

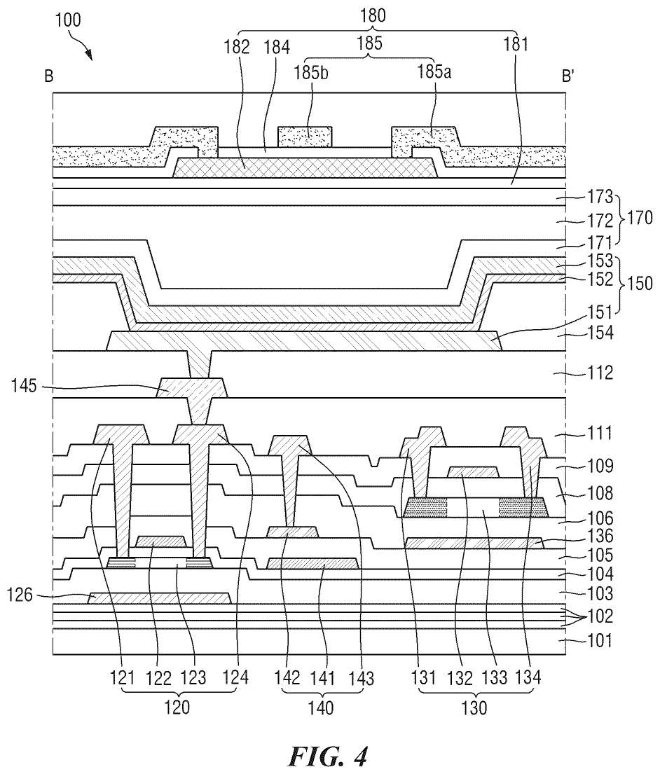

FIG. 4 is a cross-sectional view of the display panel 100 of FIG. 2 along line B-B′ in FIG. 2.

Referring to FIG. 4, the display panel 100 may include a substrate 101, a first thin film transistor 120, a second thin film transistor 130, a light-emitting part 150 or light emitting assembly 150, an encapsulation part 170, and a touch part 180 or touch sensor array 180.

The substrate 101 may include one or more plastic materials. For example, the substrate 101 may be a multi-substrate or multi-layer substrate including a plurality of plastic materials such as polyimide, but embodiments of the present disclosure are not limited thereto.

A buffer layer 102 may be disposed on the substrate 101. The buffer layer 102 may minimize or delay the diffusion of moisture or oxygen penetrating into the substrate 101. The buffer layer 102 may be formed by alternately stacking silicon nitride (SiNx) and silicon oxide (SiOx) at least once, but embodiments of the present disclosure are not limited thereto.

A first light-shielding layer 126 may be disposed on the buffer layer 102. The first light-shielding layer 126 may prevent light from transmitting through a first semiconductor layer 123 of the first thin film transistor 120. For example, the first semiconductor layer 123 may be disposed to overlap the first light-shielding layer 126. The first light-shielding layer 126 may be formed as a single layer or multiple layers of any one of molybdenum (Mo), aluminum (Al), chromium (Cr), nickel (Ni), neodymium (Nd), and copper (Cu), or an alloy thereof. However, embodiments of the present disclosure are not limited thereto.

A first insulating layer 103 may be disposed on the first light-shielding layer 126. The first insulating layer 103 may prevent a short circuit between the component of the first thin film transistor 120 and the first light-shielding layer 126. The first insulating layer 103 may be formed of the same material as that of the buffer layer 102. However, embodiments of the present disclosure are not limited thereto. For example, the first insulating layer 103 may be formed of an inorganic material such as silicon nitride (SiNx), silicon oxide (SiOx), or the like. However, embodiments of the present disclosure are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include an oxide semiconductor material such as indium-gallium-zinc oxide (IGZO), and a semiconductor material such as amorphous silicon, low temperature polycrystalline silicon, polycrystalline silicon, or the like. However, the embodiments of the present disclosure are not limited thereto. The first semiconductor layer 123 may include a channel region, a source region, and a drain region.

A low-temperature polycrystalline semiconductor layer or a polycrystalline semiconductor layer has a higher mobility than those of an amorphous semiconductor layer and an oxide semiconductor layer, so that it may have a lower power consumption and an excellent reliability. Accordingly, a driving transistor may be composed of the low-temperature polycrystalline semiconductor layer or the polycrystalline semiconductor layer, but embodiments of the present disclosure are not limited thereto.

A second insulating layer 104 may be disposed on the first semiconductor layer 123. The second insulating layer 104 may be formed of the same material as that of the first insulating layer 103, and may prevent a short circuit between the first semiconductor layer 123 and other components of the first thin film transistor 120.

The first gate electrode 122 may be disposed on the second insulating layer 104. The first gate electrode 122 may be disposed on the second insulating layer 104 in such a way as to overlap the channel region of the first semiconductor layer 123. The first gate electrode 122 may be formed as a single layer or multi-layers including molybdenum (Mo), copper (Cu), titanium (Ti), aluminum (Al), chromium (Cr), gold (Au), nickel (Ni), neodymium (Nd), or a compound thereof, but embodiments of the present disclosure are not limited thereto. The first gate electrode 122 may be disposed together with a gate line.

A third insulating layer 105 may be disposed on the first gate electrode 122. The third insulating layer 105 may be formed of the same material as that of the first insulating layer 103 or the second insulating layer 104, but embodiments of the present disclosure are not limited thereto.

The first source electrode 121 and the first drain electrode 124 may be disposed on the third insulating layer 105.

The first source electrode 121 and the first drain electrode 124 may be electrically connected to the first semiconductor layer 123 through a contact hole. The first source electrode 121 and the first drain electrode 124 may be formed of a metal material. For example, the first source electrode 121 and the first drain electrode 124 may be formed as a single layer or multiple layers of any one of molybdenum (Mo), aluminum (Al), chromium (Cr), gold (Au, titanium (Ti), nickel (Ni), neodymium (Nd), and copper (Cu), or an alloy thereof, but embodiments of the present disclosure are not limited thereto.

The first source electrode 121 and the first drain electrode 124 may be disposed together with a data line. For example, the data line may be formed of the same material and on the same layer as the first source electrode 121 and the first drain electrode 124, but embodiments of the present disclosure are not limited thereto.

A storage electrode 140 may be disposed spaced apart from the first thin film transistor 120. The storage electrode 140 may include a first storage electrode 141, a second storage electrode 142, and a third storage electrode 143.

The first storage electrode 141 may be formed of the same material and on the same layer as the first gate electrode 122, but embodiments of the present disclosure are not limited thereto.

The second storage electrode 142 may be disposed on the first storage electrode 141. The second storage electrode 142 may be disposed on the third insulating layer 105, and a capacitance may be formed by the third insulating layer 105 between the first storage electrode 141 and the second storage electrode 142 as a dielectric. The second storage electrode 142 may be formed of the same material as that of the first storage electrode 141, but embodiments of the present disclosure are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-shielding layer 136 may be disposed on the same layer as the second storage electrode 142.

The second light-shielding layer 136 may prevent light toward the second semiconductor layer 133 in a similar manner to the first light-shielding layer 126, thereby extending a lifespan of the second thin film transistor 130. For example, the second semiconductor layer 133 may be disposed to overlap the second light-shielding layer 136.

A fourth insulating layer 106 may be disposed on the second light-shielding layer 136. The fourth insulating layer 106 may be formed of the same material as that of the first insulating layer 103, the second insulating layer 104, or the third insulating layer 105, but embodiments of the present disclosure are not limited thereto.

The second semiconductor layer 133 may be disposed on the fourth insulating layer 106. The second semiconductor layer 133 may include a source region, a drain region, and a channel region between the source region and the drain region.

The second semiconductor layer 133 may include an oxide semiconductor material such as indium-gallium-zinc oxide (IGZO), and a semiconductor material such as amorphous silicon, low temperature polycrystalline silicon, polycrystalline silicon, or the like. However, embodiments of the present disclosure are not limited thereto.

A fifth insulating layer 108 may be disposed on the second semiconductor layer 133. The fifth insulating layer 108 may be formed of the same material as that of the first insulating layer 103, the second insulating layer 104, the third insulating layer 105, or the fourth insulating layer 106, but embodiments of the present disclosure are not limited thereto.

The second gate electrode 132 may be disposed on the fifth insulating layer 108.

The second gate electrode 132 may be formed of the same material as that of the first gate electrode 122, but embodiments of the present disclosure are not limited thereto. For example, the second gate electrode 132 may be formed as a single layer or multi-layers including molybdenum (Mo), copper (Cu), titanium (Ti), aluminum (Al), chromium (Cr), gold (Au), nickel (Ni), neodymium (Nd), or a compound thereof, but embodiments of the present disclosure are not limited thereto.

A sixth insulating layer 109 may be disposed on the second gate electrode 132. The sixth insulating layer 109 may be formed of the same material as that of the first insulating layer 103, the second insulating layer 104, the third insulating layer 105, the fourth insulating layer 106, or the fifth insulating layer 108, but embodiments of the present disclosure are not limited thereto.

The first source electrode 121, the first drain electrode 124, the third storage electrode 143, the second source electrode 131, and the second drain electrode 134 may be disposed on the sixth insulating layer 109.

The third storage electrode 143, the second source electrode 131, and the second drain electrode 134 may be formed of the same material as those of the first source electrode 121 and the first drain electrode 124 and may be disposed on the same layer as the first source electrode 121 and the first drain electrode 124, but embodiments of the present disclosure are not limited thereto. For example, the third storage electrode 143, the second source electrode 131, and the second drain electrode 134 may be formed as a single layer or multiple layers of any one of molybdenum (Mo), aluminum (Al), chromium (Cr), gold (Au), titanium (Ti), nickel (Ni), neodymium (Nd), and copper (Cu), or an alloy thereof, but embodiments of the present disclosure are not limited thereto.

The first thin film transistor 120 may be a driving transistor, and the second thin film transistor 130 may be a switching transistor, but embodiments of the present disclosure are not limited thereto.

A first protective layer 111 may be disposed on the first source electrode 121 and the first drain electrode 124.

The first protective layer 111 may planarize an upper portion or upper surfaces of the first thin film transistor 120 and protect the first thin film transistor 120. The first protective layer 111 may be formed of an organic material. For example, the first protective layer 111 may be formed of an organic material including acrylic resin, epoxy resin, phenolic resin, polyamide resin, or polyimide resin, but embodiments of the present disclosure are not limited thereto.

A second protective layer 112 may be disposed on the first protective layer 111. The second protective layer 112 may be formed of the same material as that of the first protective layer 111, but embodiments of the present disclosure are not limited thereto.

A connection electrode 145 may be disposed between the first protective layer 111 and the second protective layer 112.

The connection electrode 145 may electrically connect the first thin film transistor 120 and the light-emitting part 150. The connection electrode 145 may be formed of the same material as those of the first source electrode 121 and the first drain electrode 124, but embodiments of the present disclosure are not limited thereto.

The connection electrode 145 may be formed as a single layer or multiple layers of any one of molybdenum (Mo), aluminum (Al), chromium Cr, gold Au, titanium (Ti), nickel Ni, neodymium (Nd), and copper (Cu), or an alloy thereof, but embodiments of the present disclosure are not limited thereto.

The light-emitting part 150 or light emitting assembly 150 may be disposed on the second protective layer 112. The light-emitting part 150 may include an anode electrode 151, an organic layer 152, and a cathode electrode 153.

The anode electrode 151 may be disposed on the second protective layer 112. The anode electrode 151 may be electrically connected to the first thin film transistor 120 through a contact hole formed in the second protective layer 112. The anode electrode 151 may be a reflective electrode or a transparent electrode for reflecting light, but embodiments of the present disclosure are not limited thereto. The anode electrode 151 may include a metal material having a high reflectance such as a stacked structure of aluminum Al and titanium Ti (Ti/Al/Ti), a stacked structure of aluminum (Al) and ITO (ITO/Al/ITO), an APC alloy, and may be formed as a single layer or multiple layers. However, embodiments of the present disclosure are not limited thereto.

The organic layer 152 may be disposed on the anode electrode 151. The organic layer 152 may include one or more light emitting structures (or a light emitting device or element) in which a hole transport layer and an electron transport layer are stacked on the anode electrode 151 in the order listed or in the reverse order thereof. For example, the hole transport layer may include a hole injection layer, an electron blocking layer, a P-type charge generation layer, or the like, but embodiments of the present disclosure are not limited thereto. For example, the electron transport layer may include an electron injection layer, a hole blocking layer, an N-type charge generation layer, or the like, but embodiments of the present disclosure are not limited thereto. The organic layer 152 may be an organic light emitting layer, an inorganic light emitting layer, a quantum dot light emitting layer, a micro light emitting diode, a micro mini light emitting diode, or the like, but embodiments of the present disclosure are not limited thereto. For example, the organic layer 152 of the display panel 100 according to an embodiment of the present disclosure may include an organic light emitting layer. The organic layer 152 may include a red light emitting layer, a green light emitting layer, and a blue light emitting layer. The organic layer 152 may further include a white light emitting layer, but embodiments of the present disclosure are not limited thereto.

The cathode electrode 153 may be disposed on the organic layer 152. The cathode electrode 153 may be a transparent electrode or a reflective electrode for transmitting light, but the embodiments of the present disclosure are not limited thereto. For example, the cathode electrode 153 may include a transparent conductive material such as indium tin oxide (ITO) or indium zinc oxide (IZO), or a metal that transmits visible light.

The bank 154 may be disposed to expose the anode electrode 151. The bank 154 may define an opening (or emission region) of a subpixel and may be disposed to cover an edge portion of the anode electrode 151. Each subpixel may include a red emission region, a green emission region, and a blue emission region. Each subpixel may further include a white emission region. For example, the subpixel may be a pixel, but is not limited to terms. The bank 154 may be composed of a material including a black pigment, etc., or an organic material such as a benzocyclobutene resin, a polyimide resin, an acrylic resin, or a photosensitive polymer, but embodiments of the present disclosure are not limited thereto. When the bank 154 is formed of a material including a black pigment, a black dye, etc., the bank 154 may be a black bank. When the bank 154 is formed of a material including a black pigment or a black dye, the bank is able to block external light or to block light reflected from the outside, so that the luminance of the display apparatus may be further improved.

The encapsulation part 170 may be disposed on the bank 154 or the light-emitting part 150. The encapsulation part 170 may include one or more insulating layers. For example, the encapsulation part 170 may include a first encapsulation layer 171, a second encapsulation layer 172 on the first encapsulation layer 171, and a third encapsulation layer 173 on the second encapsulation layer 172. The encapsulation part 170 may include one or more inorganic material layers and one or more organic material layers. For example, the first encapsulation layer 171 and the third encapsulation layer 173 may include an inorganic material, and the second encapsulation layer 172 may include an organic material, but embodiments of the present disclosure are not limited thereto.

The touch part 180 or touch sensor array 180 may include a touch buffer layer 181 that may be disposed on the encapsulation part 170. For example, the touch buffer layer 181 may be disposed on the third encapsulation layer 173. The touch buffer layer 181 may be formed of the same material as that of the buffer layer 102, but embodiments of the present disclosure are not limited thereto. The array 180 may further include touch insulating layer 184 which may be disposed on the touch buffer layer 181. The touch insulating layer 184 may prevent a short circuit between touch electrodes. The touch insulating layer 184 may be formed of silicon oxide (SiOx), silicon nitride (SiNx), or a multilayer thereof, but embodiments of the present disclosure are not limited thereto. The array 180 may further include a first touch electrode 185 which may be disposed on the touch insulating layer 184. The first touch electrode 185 may include a 1a-th touch electrode 185a extending in a first direction and a 1b-th touch electrode 185b extending in a second direction different from the first direction.

The array 180 may also include a second touch electrode 182 that may be disposed between the touch buffer layer 181 and the touch insulating layer 184.

The second touch electrode 182 may be electrically connected to the 1a-th touch electrode 185a through a contact hole formed in the touch insulating layer 184. For example, the 1a-th touch electrode 185a and the second touch electrode 182 may extend in the first direction.

The first touch electrode 185 and the second touch electrode 182 may include a metal material. For example, the first and second touch electrodes 185 and 182 may be formed of titanium (Ti), nickel (Ni), aluminum (Al), or an alloy thereof, or may be formed to have a three-layer such as titanium (Ti)/aluminum (Al)/titanium (Ti), but embodiments of the present disclosure are not limited thereto.

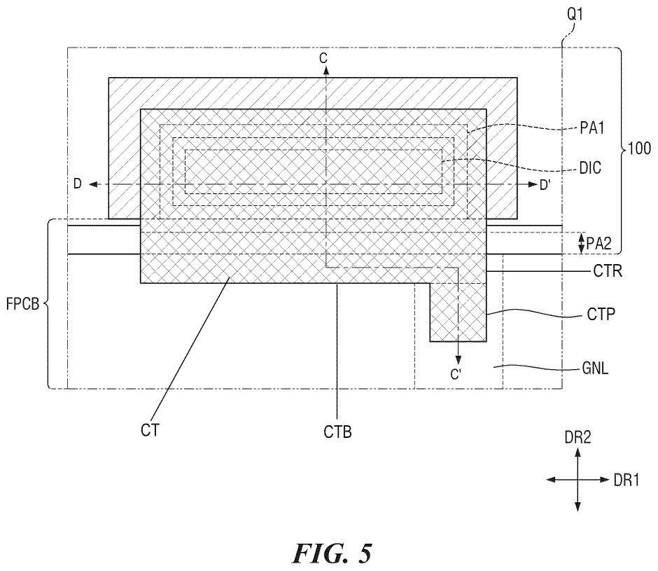

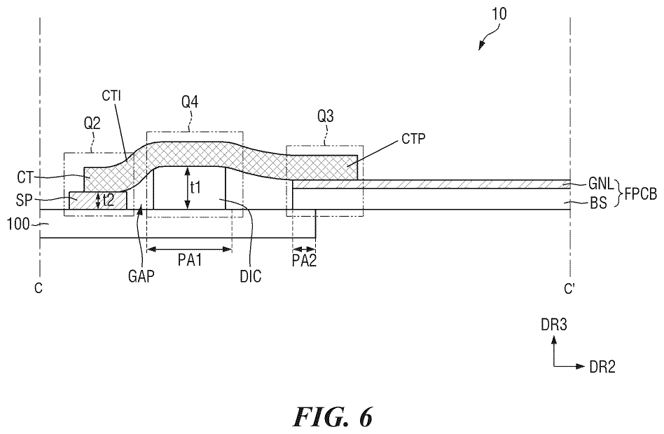

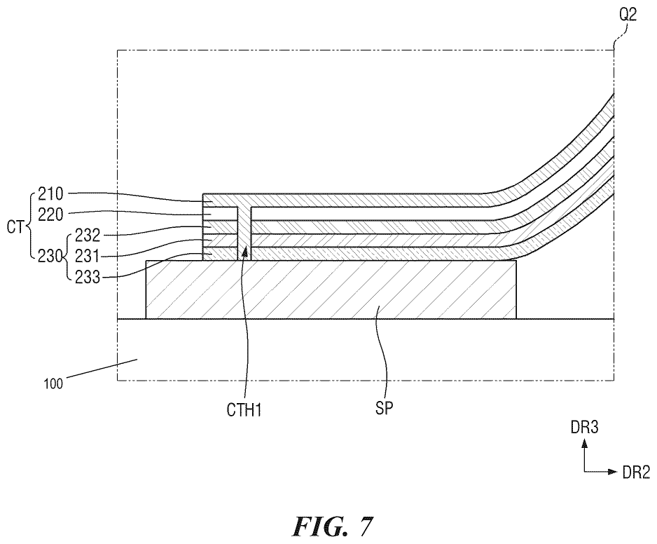

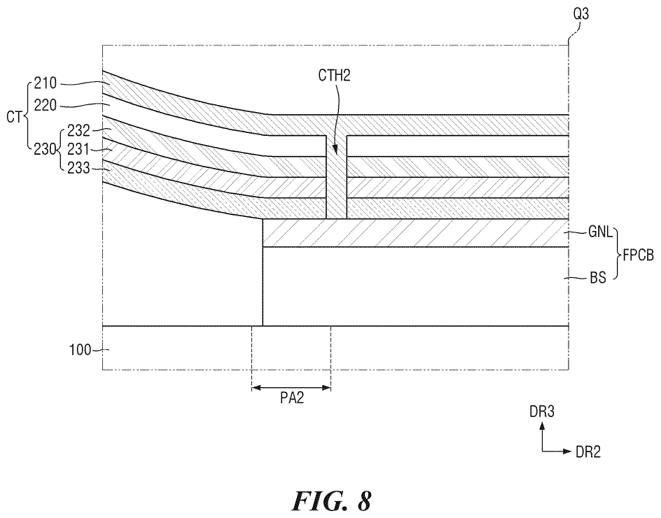

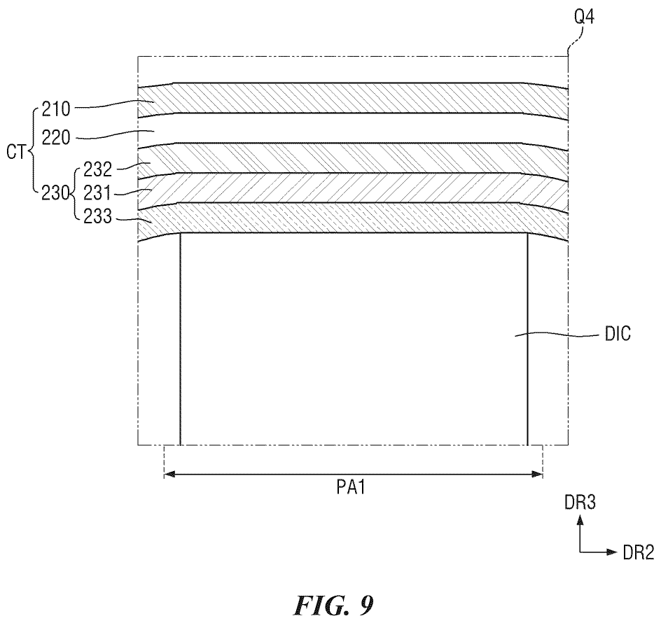

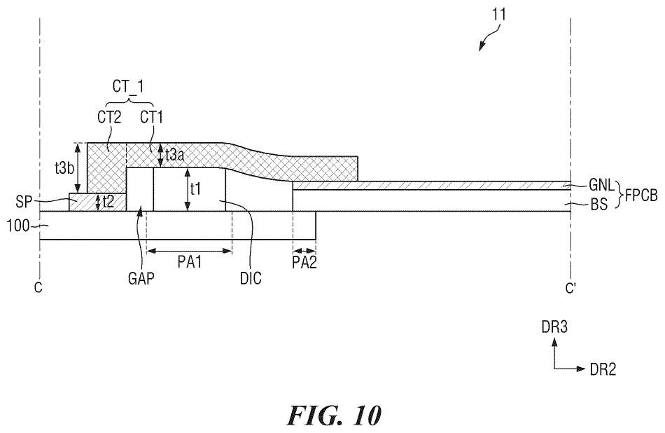

FIG. 5 is an enlarged plan view of a region Q1 of FIG. 1 according to an embodiment of the present disclosure. FIG. 6 is a cross-sectional view taken along line C-C′ of FIG. 5 according to an embodiment of the present disclosure. FIG. 7 is an enlarged plan view of a region Q2 of FIG. 6 according to an embodiment of the present disclosure. FIG. 8 is an enlarged plan view of a region Q3 of FIG. 6 according to an embodiment of the present disclosure. FIG. 9 is an enlarged plan view of a region Q4 of FIG. 6 according to an embodiment of the present disclosure. FIG. 10 is a cross-sectional view taken along line D-D′ in FIG. 5 according to an embodiment of the present disclosure.

Referring to FIGS. 5 to 10, the display apparatus 10 according to an embodiment of the present disclosure may include the display panel 100 and a printed circuit board FPCB. Since the description of the display panel 100 is substantially the same as the description with reference to FIGS. 1 to 4, the repetitive descriptions thereof may be omitted or briefly described.

Referring to FIGS. 5 to 10, the display panel 100 according to an embodiment of the present disclosure may include the data driving part DIC and the plurality of pad areas PA1 and PA2. Since the description of the data driving part DIC and the plurality of pad areas PA1 and PA2 is substantially the same as the description with reference to FIGS. 1 to 4, the repetitive descriptions thereof may be omitted or briefly described.

For example, the data driving part DIC may be disposed at the first pad area PAL. The second pad area PA2 may be at the printed circuit board FPCB.

As shown in FIG. 5, a ground line GNL may be formed at the printed circuit board FPCB. The connection member CT may have a generally rectangular shape. The connection member CT may further include a protrusion CTP which protrudes to or from the other side or bottom side in the second direction DR2 to overlap the ground line GNL of the printed circuit board FPCB. In an embodiment, the protrusion CTP extends from a right side CTR and a bottom side CTB of the connection member CT at an interface between the bottom side CTB and the right side CTR, or in other words, is planar and continuous with the right side CTR, and extends from only a portion of the bottom side CTB. In an embodiment, the protrusion CTP extends from less than a quarter of the length of the bottom side CTB to overlap the ground line GNL. Other configurations are possible depending on the location of the ground line GNL. The length in the second direction DR2 of the connection member CT in which the protrusion CTP is formed may be greater than the length in the second direction DR2 of the connection member CT in which the protrusion is not formed. In other words, the section or portion of the connection member CT that includes the protrusion CTP has a length in the second direction DR2 that is greater than a length of the section or portion of the connection member CT that does not include the protrusion. The data driving part DIC and the reinforcement part SP may be spaced apart from each other, as best shown in FIG. 6.

As shown in FIG. 6, the ground line GNL may be disposed on a base film BS or base substrate BS of the printed circuit board FPCB, but embodiments of the present disclosure are not limited thereto. For example, according to the display apparatus according to some embodiments of the present disclosure, the printed circuit board FPCB may further include an insulating layer on the ground line GNL, and in the region where the ground line GNL of FIG. 5 is disposed, the insulating layer may expose the ground line GNL. However, embodiments of the present disclosure are not limited thereto.

As shown in FIG. 6, the connection member CT may adjoin the data driving part DIC, the reinforcement part SP, and the printed circuit board FPCB. For example, the connection member CT may be directly coupled with or directly formed on the data driving part DIC, the reinforcement part SP, and the printed circuit board FPCB. The data driving part DIC may have a first thickness t1, and the reinforcement part SP may have a second thickness t2. The first thickness t1 may be the thickness of the data driving part DIC in a third direction DR3. The second thickness t2 may be the thickness of the reinforcement part SP in the third direction DR3. A space (or a separation space) GAP may be a distance (or a separation distance) between the data driving part DIC and the reinforcement part SP, and may be a distance (or a separation distance) in the second direction DR2. The first thickness t1 and the second thickness t2 may be different from each other, and the first thickness t1 may be greater than the second thickness t2. Since the thickness t1 of the data driving part DIC is greater than the thickness t2 of the reinforcement part SP, the connection member CT may have an inclined surface CTI in the space GAP between the data driving part DIC and the reinforcement part SP. In an embodiment of the present disclosure, the inclined surface CTI may be any surface whose upper surface does not extend only in the second direction DR2 (i.e., any non-horizontal surface). For example, the inclined surface may include not only an inclined surface with a constant inclination (or a constant slope) but also an inclined surface with a non-constant inclination (or a non-constant slope). For example, at least a portion of the inclined surface with a non-constant inclination (or a non-constant slope) may include an inclined surface including a curved surface (or a slope), or a step up or down configuration, but embodiments of the present disclosure are not limited thereto.

As shown in FIG. 7, the connection member CT may include a plurality of layers. The connection member CT may include a connecting portion 230, an insulating portion 220 on the connecting portion 230, and a conductive portion 210 on the insulating portion 220. The connecting portion 230 may include a base material 231, a first adhesive portion 232 between the base material 231 and the insulating portion 220, and a second adhesive portion 233 between the base material 231 and the reinforcement part SP. The base material 231 may include polyethylene terephthalate (PET), but embodiments of the present disclosure are not limited thereto. The first and second adhesive portions 232 and 233 may include a pressure sensitive adhesive (PSA), but embodiments of the present disclosure are not limited thereto. The connecting portion 230 may connect the insulating portion 220 and the reinforcement part SP therebelow. In FIG. 7, the connecting portion 230 is shown as a double-sided tape, but embodiments of the present disclosure are not limited thereto. For example, the connecting portion 230 may be formed of an adhesive material or an adhesive. Thus, the connecting portion 230 may also be referred to as an adhesive portion 230, adhesive layer or multi-layer stack 230, coupling assembly 230, connection portion 230, and other like terms.

The insulating portion 220 may include an insulating material. The insulating material may include an organic insulating material or an inorganic insulating material.

The conductive portion 210 may include a metal having a conductivity. For example, the conductive portion 210 may be formed as a single layer or multiple layers of any one of molybdenum (Mo), aluminum (Al), chromium (Cr), nickel (Ni), neodymium (Nd), and copper (Cu), or an alloy thereof, alone or in any combination. However, embodiments of the present disclosure are not limited thereto. The conductive portion 210 may include a first contact hole CTH1 that passes through the insulating portion 220 and the connecting portion 230. For example, in or through the first contact hole CTH1, the conductive portion 210 may be exposed to the reinforcement part SP. The conductive portion 210 exposed to the reinforcement part SP in the first contact hole CTH1 may contact and be electrically connected to the reinforcement part SP. For example, the conductive portion 210 exposed to the reinforcement part SP in the first contact hole CTH1 may directly contact and be electrically connected to the reinforcement part SP. The first contact hole CTH1 may contact and be electrically connected to the reinforcement part SP. For example, the first contact hole CTH1 may directly contact and be electrically connected to the reinforcement part SP. As shown in FIG. 7, the first contact hole CTH1 extends through all of the layers of the connection member CT, except the conductive portion 210. As such, the first contact hole CTH1 enables a direct electrical contact and connection between the conductive portion 210 and the reinforcement part SP. In an embodiment, any of the “portions” described above with reference to FIG. 7 may also be layers or multi-layer stacks or laminates, unless otherwise noted.

In the display apparatus 10 according to an embodiment of the present disclosure, the connection member CT is electrically connected to the reinforcement part SP, thereby increasing an electrical ground path. According to an embodiment of the present disclosure, the reinforcement part SP may include a metal material. The reinforcement part SP of the metal material may be utilized as a ground path. For example, the ground path may be the display panel 100, the conductive portion 210 of the connection member CT, and the printed circuit board FPCB. The conductive portion 210 of the connection member CT may be electrically connected to the reinforcement part SP directly disposed on the display panel 100, thereby providing a ground path to the display panel 100 given that the reinforcement part SP may be disposed and in some cases directly disposed on the display panel 100. FIG. 7 illustrates only the electrical connection between the connection member CT and the reinforcement part SP on one side (i.e., a left side) of the data driving part DIC in the second direction DR2. In an embodiment, the electrical connection between the conductive portion 210 and the reinforcement part SP shown in FIG. 7 may also be applied to the connection member CT and the reinforcement part SP on one side (i.e., a left side) and the other side (i.e., at least one of a right side, a front side and a back side) of the data driving part DIC in the first direction DR1. The reinforcement part SP may be disposed to surround the periphery of the data driving part DIC. The connection member CT may be electrically connected to the reinforcement part SP surrounding the periphery of the data driving part DIC, and the reinforcement part SP may be formed of a metal material, so that the ground path may be formed. For example, the reinforcement part SP may function as an earth or ground terminal and the printed circuit board FPCB may include the ground line GNL. Also, the connection member CT may connect the ground line GNL and the earth terminal (reinforcement part SP). Further, the connection member CT shields the data driving part DIC, thereby preventing static electricity generation. Therefore, the connection member CT may be an integral connection member that prevents static electricity and performs a grounding function.

As shown in FIG. 8, the connection member CT may be attached to the printed circuit board FPCB. The connection member CT may be attached to the printed circuit board FPCB through the second adhesive portion 233 described in FIG. 7. The conductive portion 210 may be exposed in the region where the conductive portion 210 overlaps the printed circuit board FPCB. The conductive portion 210 may be electrically connected to the printed circuit board FPCB through a second contact hole CTH2 that passes through all layers of the insulating portion 220 and the connecting portion 230. The second contact hole CTH2 may be located overlapping, or at a boundary of, the second pad area PA2 in some embodiments.

As shown in FIG. 9, the connection member CT may be attached to the data driving part DIC. The connection member CT may be attached to the data driving part DIC through the second adhesive portion 233 described in FIG. 7. The conductive portion 210 of the connection member CT may not be exposed on the data driving part DIC. Accordingly, the connection member CT may be a multi-layer stack that extends over, and is physically coupled or directly physically attached, but not electrically coupled to the data driving part DIC.

Hereinafter, a display apparatus 11 according to an embodiment of the present disclosure will be described. For the same or similar reference numerals as those of the above description, repetitive descriptions thereof may be omitted or briefly described.

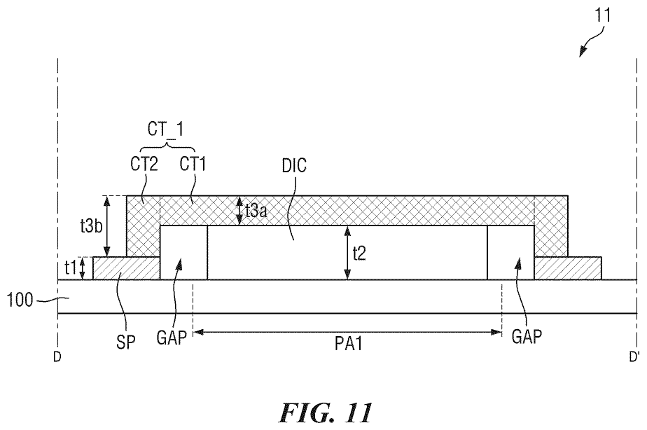

FIG. 10 is a cross-sectional view of the display apparatus 11 according to an embodiment of the present disclosure. FIG. 11 is a cross-sectional view of the display apparatus 11 according to an embodiment of the present disclosure. While FIG. 10 and FIG. 11 illustrate an embodiment of a display apparatus 11 that is different from the display apparatus 10 as noted below, for clarity of the disclosure, the views in FIG. 10 and FIG. 11 are taken along the lines C-C′ and D-D′ in FIG. 5.

Referring to FIGS. 10 and 11, a connection member CT_1 of a display apparatus 11 according to an embodiment of the present disclosure may have different thicknesses for each region.

Beginning with FIG. 5 and referring to FIGS. 10 and 11, the connection member CT may contact the data driving part DIC, the reinforcement part SP, and the printed circuit board FPCB. Since the thickness t1 of the data driving part DIC is larger than the thickness t2 of the reinforcement part SP, the connection member CT may have an inclined surface in the space GAP between the data driving part DIC and the reinforcement part SP. Near the inclined surface of the connection member CT, the connection member CT may be more likely to peel off from the upper surface of the reinforcement part SP or the upper surface of the data driving part DIC. If the connection member CT peels off from the upper surface of the reinforcement part SP or the upper surface of the data driving part DIC, an adhesion area between the connection member CT and the reinforcement part SP or between the connection member CT and the data driving part DIC may be reduced, causing poor adhesion.

Additionally, an air gap may be formed between the inclined surface of the connection member CT and the upper surface of the reinforcement part SP or the upper surface of the data driving part DIC. Due to the air gap, bubbles may be formed on the surface of the second adhesive portion (see reference numeral 233 of FIG. 7) of the connecting portion (see reference numeral 230 of FIG. 7) of the connection member CT. The bubbles formed on the surface of the second adhesive portion (see reference numeral 233 of FIG. 7) of the connecting portion (see reference numeral 230 of FIG. 7) of the connection member CT may cause poor adhesion between the connection member CT and the reinforcement part SP or between the connection member CT and the data driving part DIC.

According to an embodiment of the present disclosure, the connection member CT_1 may compensate for a step difference between the data driving part DIC and the reinforcement part SP. For example, the connection member CT_1 may be configured to have a larger thickness at the reinforcement part SP in order to compensate for a height difference between the data driving part DIC and the reinforcement part SP. Thus, no inclined surface may formed on the connection member CT_1, and an adhesive force or an attaching force between the connection member CT_1 and the underlying reinforcement part SP or the data driving part DIC may be further improved. As a result, the connection member CT_1 is flat and horizontal in regions overlapping the reinforcement part SP and the data driving part DIC.

The connection member CT_1 may include a first portion CT1 and a second portion CT2. The first portion CT1 may overlap the data driving part DIC, the printed circuit board FPCB, the spaced space GAP between the data driving part DIC and the reinforcement part SP, and a space (or a separation space) between the data driving part DIC and the printed circuit board FPCB. The second portion CT2 may overlap the reinforcement part SP. The first portion CT1 may have a third thickness t3a. The second portion CT2 may overlap only the reinforcement part SP and have a fourth thickness t3b. The fourth thickness t3b may be greater than the third thickness t3a. The difference between the fourth thickness t3b and the third thickness t3a may be the same as the difference between the first thickness t1 and the second thickness t2.

In the display apparatus 11 according to FIGS. 10 and 11, the second portion CT2 of the connection member CT_1, which has the fourth thickness t3b, overlaps the reinforcement part SP. Accordingly, in the space GAP between the data driving part DIC and the reinforcement part SP, the connection member CT_1 may be disposed flat without an inclined surface (or a slope). Accordingly, it is possible to further resolve potential issues with the connection member CT_1 peeling off at a portion where the connection member CT_1 is connected to the upper surface of the reinforcement part SP or the upper surface of the data driving part DIC. As a result, it is possible to further improve the poor adhesion that may occur due to when the connection member CT_1 peels off from the upper surface of the reinforcement part SP or the upper surface of the data driving part DIC.

Also, since the connection member CT_1 is disposed flat without an inclined surface (or a slope) in the space GAP between the data driving part DIC and the reinforcement part SP, an air gap may be prevented in advance from being formed between the upper surface of the reinforcement part SP of the connection member CT_1 and the upper surface of the data driving part DIC.

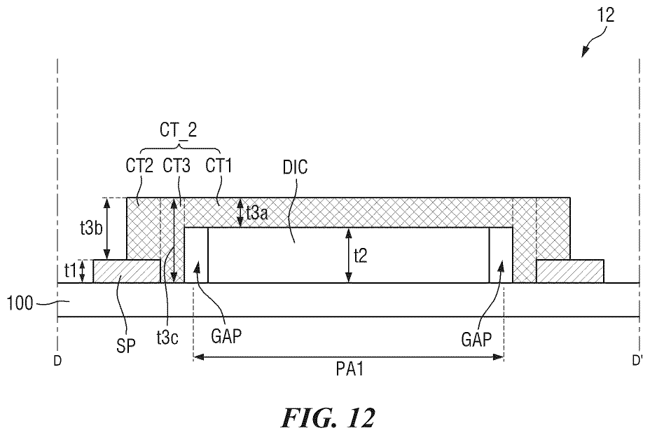

FIG. 12 is a cross-sectional view of a display apparatus 12 according to an embodiment of the present disclosure. FIG. 12 is taken along line D-D′ in FIG. 5 for clarity even though the display apparatus 10 may differ from apparatus 12 as noted below.

Referring to FIG. 12, a connection member CT_2 of a display apparatus 12 according to another embodiment of the present disclosure may further include a third portion CT3.

The third portion CT3 may be disposed between the first portion CT1 and the second part or portion CT2. The third portion CT3 may be disposed in at least a part or portion of the space (or the separation space) GAP between the data driving part DIC and the reinforcement part SP. The third portion CT3 may have a fifth thickness t3c. The fifth thickness t3c may be greater than the fourth thickness t3b. The difference between the fifth thickness t3c and the third thickness t3a may be the same as the thickness t1 of the data driving part DIC.

According to the display apparatus 12 of FIG. 12, the third portion CT3 may be attached to the upper surface of the display panel 100. For example, the third portion CT3 may be directly attached to the upper surface of the display panel 100. As a result, the adhesive force between the connection member CT_2 and the members SP, DIC, and 100 below the connection member CT_2 may be further enhanced. Also, since the connection member CT_2 is additionally coupled to the display panel 100 between the data driving part DIC and the reinforcement part SP, the connection member CT_2 may be less likely to (or may reduce) peel off from the reinforcement part SP or the data driving part DIC.

For example, the width of the third portion CT3 may be less than the width of the space GAP. Since the width of the third portion CT3 is less than the width of the space GAP, when the connection member CT_2 is attached to the data driving part DIC and the reinforcement part SP, even though an align miss occurs, the third portion CT3 may avoid overlapping with the data driving part DIC or the reinforcement part SP. In an embodiment, the third portion CT3 extends along a side surface (i.e., a right side surface) of the reinforcement part SP, but as noted above, preferably does not fill the space GAP to avoid contact with the data driving part DIC. In some embodiments, the third portion CT3 is spaced from both the reinforcement part SP and the data driving part DIC, depending on the installation location. Further, the third portion CT3 may fill, on its own or with other layers, the space GAP in some embodiments.

The display apparatus according to various embodiments of the present disclosure may be applied to mobile devices, video phones, smart watches, watch phones, wearable apparatuses, foldable apparatuses, rollable apparatuses, bendable apparatuses, flexible apparatuses, curved apparatuses, sliding apparatuses, variable apparatuses, electronic notebooks, electronic books, portable multimedia players (PMPs), personal digital assistants (PDAs), MP3 players, mobile medical equipment, desktop PCs, laptop PCs, netbook computers, workstations, navigation apparatuses, vehicle navigation apparatuses, vehicle display apparatuses, vehicle apparatuses, theater apparatuses, theater display apparatuses, televisions, wallpaper apparatuses, signage apparatuses, game apparatuses, laptops, monitors, cameras, camcorders, and home appliances, etc.

A display apparatus according to various embodiments of the present disclosure may be described as follows.

A display apparatus according to various embodiments of the present disclosure may include a display panel including a display area having a plurality of pixels, and a first pad area disposed around the display area, a data driving part on the first pad area, and a connection member on the data driving part. The connection member may have different thicknesses according to a portion thereof disposed in the data driving part.

According to various embodiments of the present disclosure, the connection member may cover the data driving part.

According to various embodiments of the present disclosure, the display apparatus may further include a reinforcement part disposed around the data driving part and spaced apart from the data driving part.

According to various embodiments of the present disclosure, a thickness of the data driving part may be greater than a thickness of the supplement part.

According to various embodiments of the present disclosure, the connection member may include a first portion and a second portion overlapping the supplement part. The thickness of the second portion may be greater than the thickness of the first portion.

According to various embodiments of the present disclosure, the first portion may overlap the data driving part.

According to various embodiments of the present disclosure, the first portion may be disposed at a space between the data driving part and the supplement part.

According to various embodiments of the present disclosure, the connection member may further include a third portion that overlaps a space between the data driving part and the supplement part. The thickness of the third portion may be greater than the thickness of the second portion.

According to various embodiments of the present disclosure, the connection member may include a connecting portion and a conductive portion on the connecting portion.

According to various embodiments of the present disclosure, the connection part of the first part may be attached to the data driver. The connection portion of the second portion may be attached to the supplement part.

According to various embodiments of the present disclosure, the conductive portion of the second portion may contact the supplement part.

According to various embodiments of the present disclosure, the display panel may further include a second pad area. The display apparatus may further include a printed circuit board located in the second pad area. The first portion of the connection member may overlap a portion of the printed circuit board.

According to various embodiments of the present disclosure, the printed circuit board may further include a ground line. The conductive portion of the first portion of the connection member may contact the ground line.

According to various embodiments of the present disclosure, the reinforcement part may not be disposed between the data driving part and the second pad area.

The display apparatus according to various embodiments of the present disclosure may include a display panel including a display area having a plurality of pixels, and a first pad area disposed around the display area, a data driving part disposed on the first pad area, and a connection member covering the data driving part. The connection member may include no inclined surface.

According to various embodiments of the present disclosure, the connection member may cover the data driving part.

According to various embodiments of the present disclosure, the display apparatus may further include a reinforcement part disposed around the data driving part and spaced apart from the data driving part. The connection member and the reinforcement part may be electrically connected to each other.

According to various embodiments of the present disclosure, the display panel may further include a second pad area. The display apparatus may further include a printed circuit board at the second pad area. The connection member may be electrically connected to the printed circuit board.

According to various embodiments of the present disclosure, the connection member may include a connecting portion and a conductive portion on the connecting portion. The conductive portion may be electrically connected to the reinforcement part and the printed circuit board.

According to various embodiments of the present disclosure, the reinforcement part may not be disposed between the data driving part and the second pad area.

It will be apparent to those skilled in the art that various modifications and variations can be made in the present disclosure without departing from the scope of the disclosures. Thus, it is intended that the present disclosure covers the modifications and variations of this disclosure provided that within the scope of the appended claims and their equivalents.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a display panel having a plurality of pixels in a display area, the display panel further including a first pad area disposed around the display area;
a data driving circuit disposed on the first pad area of the display panel; and
a connection member disposed on the data driving circuit,
wherein the connection member has a first portion and a second portion overlapping different regions of the display panel, the first portion having a different thickness from the second portion.

2. The display apparatus of claim 1, wherein the connection member covers the data driving part.

3. The display apparatus of claim 1, further comprising:
a reinforcement layer disposed around the data driving circuit and spaced apart from the data driving circuit,
wherein the first portion overlaps the data driving circuit and the second portion overlaps the reinforcement layer.

4. The display apparatus of claim 3, wherein a thickness of the data driving circuit is greater than a thickness of the reinforcement layer, and wherein a thickness of the second portion is greater than a thickness of the first portion.

5. A display apparatus, comprising:
a display panel having a display area;
a data driving circuit disposed on the display panel;
a reinforcement layer disposed on the display panel and spaced apart from the data driving circuit; and
a connection member disposed on the data driving circuit,
wherein the connection member has a first portion and a second portion overlapping different regions of the display panel,
wherein the second portion overlaps the reinforcement layer, and
wherein a thickness of the second portion is greater than a thickness of the first portion.

6. The display apparatus of claim 5, wherein the first portion overlaps the data driving circuit.

7. The display apparatus of claim 5, wherein the first portion is disposed over a space between the data driving circuit and the reinforcement layer.

8. The display apparatus of claim 7,
wherein the connection member further comprises a third portion between the first portion and the second portion that overlaps the space between the data driving circuit and the reinforcement layer, and
wherein a thickness of the third portion is greater than the thickness of the second portion.

9. The display apparatus of claim 5, wherein the connection member comprises a connecting portion and a conductive portion disposed on the connecting portion, the connecting portion and the conductive portion being present in the first portion and the second portion of the connection member.

10. The display apparatus of claim 9,
wherein the connecting portion of the first portion is coupled to the data driving circuit, and
wherein the connecting portion of the second portion is coupled to the reinforcement layer.

11. The display apparatus of claim 10, wherein the conductive portion of the second portion contacts the reinforcement layer.

12. The display apparatus of claim 8,
wherein the display panel further comprises a first pad area disposed around the display area and a second pad area,
wherein the display apparatus further comprises a printed circuit board disposed in the second pad area, and
wherein the first portion of the connection member overlaps a portion of the printed circuit board.

13. The display apparatus of claim 12,
wherein the printed circuit board further comprises a ground line, and
wherein the conductive portion of the first portion of the connection member contacts the ground line.

14. The display apparatus of claim 13, wherein the reinforcement layer is absent from a region of the display panel between the data driving circuit and the second pad area.

15. A display apparatus, comprising:
a display panel including a display area having a plurality of pixels, the display panel further including a first pad area disposed around the display area;
a data driving part on the first pad area; and
a connection member covering the data driving part,
wherein the connection member is horizontal.

16. The display apparatus of claim 15, wherein the connection member covers the data driving part.

17. The display apparatus of claim 15, further comprising a reinforcement part disposed around the data driving part and spaced apart from the data driving part,
wherein the connection member and the reinforcement part are electrically connected to each other.

18. The display apparatus of claim 17,
wherein the display panel further comprises a second pad area,
wherein the display apparatus further comprises a printed circuit board at the second pad area, and
wherein the connection member is electrically connected to the printed circuit board.

19. The display apparatus of claim 18,
wherein the connection member comprises a connecting portion and a conductive portion on the connecting portion, and
wherein the conductive portion is electrically connected to the reinforcement part and the printed circuit board.

20. The display apparatus of claim 18, wherein the reinforcement part is not disposed between the data driving part and the second pad area.
